(19) United States
(12) Patent Application Publication
(10) Pub. No.: US 2023/0070867 A1
(43) Pub. Date: Mar. 9, 2023

(54) ACOUSTIC WAVE DEVICE

(71) Applicant: Murata Manufacturing Co., Ltd., Nagaokakyo-shi (JP)

(72) Inventors: Masakazu MIMURA, Nagaokakyo-shi (JP); Soichiro TEGAWA, Nagaokakyo-shi (JP)

(21) Appl. No.: 17/987,930

(22) Filed: Nov. 16, 2022

Related U.S. Application Data
(63) Continuation of application No. PCT/JP2021/019338, filed on May 21, 2021.

(30) Foreign Application Priority Data
May 28, 2020 (JP) 2020-093437

(51) Int. Cl. H03H 9/25

(52) U.S. Cl. CPC H03H 9/25

(57) ABSTRACT

An acoustic wave device includes a piezoelectric substrate and an IDT electrode including electrode fingers, a first layer on the piezoelectric substrate, and a second layer on the first layer and including Cu as a main component. The first layer includes a first principal surface on a side closest to the piezoelectric substrate and a second principal surface in contact with the second layer. The second layer includes a third principal surface in contact with the first layer, a fourth principal surface opposite to the third principal surface, and a side surface connected to the third and fourth principal surfaces. The IDT electrode includes a barrier layer on the side surface of the second layer. A boundary between the side surface of the second layer and the barrier layer is on the second principal surface of the first layer, and the barrier layer does not reach the piezoelectric substrate.

### CROSS REFERENCE TO RELATED APPLICATIONS

This application claims the benefit of priority to Japanese Patent Application No. 2020-093437 filed on May 28, 2020 and is a Continuation Application of PCT Application No. PCT/JP2021/019338 filed on May 21, 2021. The entire contents of each application are hereby incorporated herein by reference.

### BACKGROUND OF THE INVENTION

### 1. Field of the Invention

The present invention relates to an acoustic wave device.

### 2. Description of the Related Art

Hitherto, acoustic wave devices have been widely used in filters for mobile phones and so on. Japanese Unexamined Patent Application Publication No. 2019-068309 discloses an example of the acoustic wave devices. In the disclosed acoustic wave device, an IDT (Interdigital Transducer) electrode is disposed on a piezoelectric substrate. The IDT electrode includes a Cu film. Moreover, a silicon oxide film is disposed on the piezoelectric substrate and covers the IDT electrode. A protective film is further disposed on the piezoelectric substrate and covers the IDT electrode to prevent Cu in the Cu film from diffusing into the silicon oxide film.

In an acoustic wave device disclosed in Japanese Unexamined Patent Application Publication No. 2017-157944, an IDT electrode includes a barrier layer disposed on a piezoelectric substrate and a main electrode layer disposed on the barrier layer. The barrier layer is disposed to prevent a metal in the main electrode layer from diffusing into the piezoelectric substrate.

### SUMMARY OF THE INVENTION

It is deemed that, when the protective film disclosed in Japanese Unexamined Patent Application Publication No. 2019-068309 is disposed on the piezoelectric substrate to cover the IDT electrode disclosed in Japanese Unexamined Patent Application Publication No. 2017-157944, the metal forming the IDT electrode can be suppressed from diffusing into the silicon oxide film and the piezoelectric substrate. However, the inventors of preferred embodiments of the present invention discovered that there is a possibility of the metal diffusing into the piezoelectric substrate through a path formed at a boundary between a side surface of the barrier layer and the protective film.

Preferred embodiments of the present invention provide acoustic wave devices each capable of more reliably reducing or preventing diffusion of Cu of an IDT electrode into a piezoelectric substrate.

A preferred embodiment of the present invention provides an acoustic wave device including a piezoelectric substrate and an IDT electrode including a plurality of electrode fingers, a first layer on the piezoelectric substrate, and a second layer on the first layer and including Cu as a main component, wherein the first layer includes a first principal surface positioned on a side closest to the piezoelectric substrate and a second principal surface in contact with the second layer, the second layer includes a third principal surface in contact with the first layer, a fourth principal surface opposite to the third principal surface, and a side surface connected to the third principal surface and the fourth principal surface, the IDT electrode further includes an outer layer on the side surface of the second layer, and a boundary between the side surface of the second layer and the outer layer is on the second principal surface of the first layer, and the outer layer does not reach the piezoelectric substrate.

With the acoustic wave devices according to preferred embodiments of the present invention, Cu of the IDT electrode can be more reliably reduced or prevented from diffusing into the piezoelectric substrate.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of an acoustic wave device according to a first preferred embodiment of the present invention.

FIG. 2 is a sectional view, taken along a line I-I in FIG. 1, of an electrode finger.

FIG. 3 is a transverse sectional view of an electrode finger in a first comparative example.

FIG. 4 is a transverse sectional view of an electrode finger in a second comparative example.

FIG. 5 is a transverse sectional view of an electrode finger in a first modification of the first preferred embodiment of the present invention.

FIG. 6 is a transverse sectional view of an electrode finger in a second modification of the first preferred embodiment of the present invention.

FIG. 7 is a transverse sectional view of an electrode finger in a third modification of the first preferred embodiment of the present invention.

FIG. 8 is a transverse sectional view of an electrode finger in a second preferred embodiment of the present invention.

FIG. 9 is a transverse sectional view of an electrode finger in a modification of the second preferred embodiment of the present invention.

FIG. 10 is a transverse sectional view of an electrode finger in a third preferred embodiment of the present invention.

FIG. 11 is a transverse sectional view of an electrode finger in a modification of the third preferred embodiment of the present invention.

FIG. 12 is a transverse sectional view of an electrode finger in a fourth preferred embodiment of the present invention.

FIG. 13 is a front sectional view of an acoustic wave device according to a fifth preferred embodiment of the present invention.

FIG. 14 is a front sectional view of an acoustic wave device according to a sixth preferred embodiment of the present invention.

FIG. 15 is a front sectional view of an acoustic wave device according to a seventh preferred embodiment of the present invention.

### DETAILED DESCRIPTION OF THE PREFERRED EMBODIMENTS

The present invention will be clarified from the following description of practical preferred embodiments of the present invention with reference to the drawings.

It is to be noted that the preferred embodiments described in this Description are merely illustrative, and that configurations in the different preferred embodiments can be partially replaced therebetween or combined with each other.

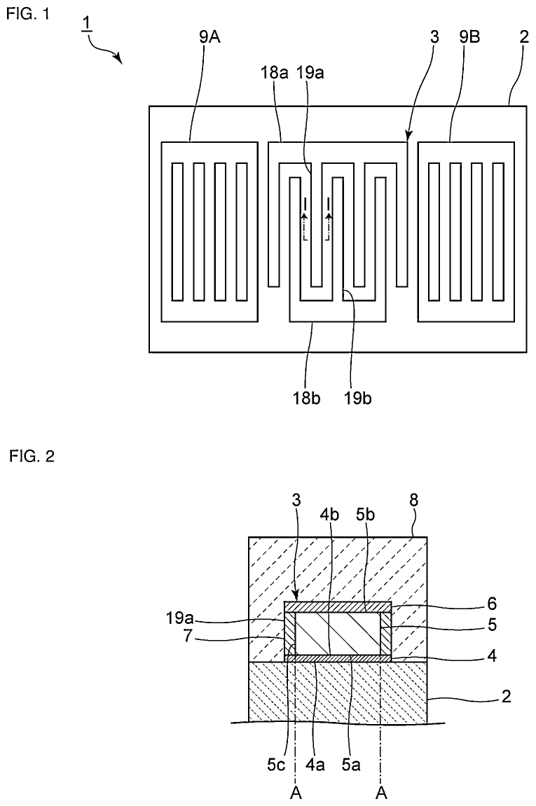

FIG. 1 is a plan view of an acoustic wave device according to a first preferred embodiment of the present invention.

The acoustic wave device 1 includes a piezoelectric substrate 2. The piezoelectric substrate 2 in this preferred embodiment is a piezoelectric substrate including only a piezoelectric layer. The piezoelectric substrate 2 is made of lithium niobate. In this Description, the wording “the piezoelectric substrate 2 is made of lithium niobate” includes the case in which the piezoelectric substrate 2 contains a trace amount of impurities. The above point is similarly applied to relations between other components of the acoustic wave devices according to preferred embodiments of the present invention and materials of those components. In more detail, the piezoelectric substrate 2 is made of 128° rotated Y cut X SAW propagation LiNbO₃. However, the cut angle and the material of the piezoelectric substrate 2 are not limited to the above-mentioned examples. In another example, lithium tantalate, zinc oxide, aluminum nitride, quartz, PZT (Pb(Zr—Ti)O₃), or the like can also be used as the material of the piezoelectric substrate 2. The piezoelectric substrate 2 may be a multilayer substrate including a piezoelectric layer.

The IDT electrode 3 is disposed on the piezoelectric substrate 2. The IDT electrode 3 includes a first busbar 18a, a second busbar 18b, a plurality of first electrode fingers 19a, and a plurality of second electrode fingers 19b. The first busbar 18a and the second busbar 18b are opposite to each other. One end of each of the first electrode fingers 19a is connected to the first busbar 18a. One end of each of the second electrode fingers 19b is connected to the second busbar 18b. The first electrode fingers 19a and the second electrode fingers 19b are interdigitated with each other. A wavelength specified by an electrode finger pitch of the IDT electrode 3 is assumed to be denoted by λ. The term “electrode finger pitch” indicates a center-to-center distance between adjacent two of the electrode fingers. When the IDT electrode 3 includes portions in which the center-to-center distances are different, the electrode finger pitch may be given by an average value of the different center-to-center distances.

When an AC voltage is applied to the IDT electrode 3, an acoustic wave is excited. A pair of reflectors 9A and 9B is disposed on the piezoelectric substrate 2 on both sides of the IDT electrode 3 in a propagation direction of the acoustic wave. Thus, the acoustic wave device 1 according to this preferred embodiment is a surface acoustic wave resonator. Alternatively, the acoustic wave devices according to preferred embodiments of the present invention may be boundary acoustic wave resonators. The acoustic wave devices according to preferred embodiments of the present invention are not limited to the acoustic wave resonator and may be a filter device or a multiplexer each including the acoustic wave resonator.

FIG. 2 is a sectional view, taken along a line I-I in FIG. 1, of the electrode finger.

The IDT electrode 3 includes a first layer 4, a second layer 5, and a third layer 6. In more detail, the first layer 4 is disposed on the piezoelectric substrate 2. The second layer 5 is disposed on the first layer 4. The third layer 6 is disposed on the second layer 5.

The first layer 4 has a first principal surface 4a and a second principal surface 4b. The first principal surface 4a and the second principal surface 4b are opposite to each other. The first principal surface 4a is positioned on a side close to the piezoelectric substrate 2. The second principal surface 4b is in contact with the second layer 5. In this preferred embodiment, the first layer 4 is a close contact layer including a single layer. The first layer 4 is made of NiCr. However, the material of the first layer 4 is not limited to the above-mentioned example. In another example, the first layer 4 may be a multilayer body.

The second layer 5 has a third principal surface 5a, a fourth principal surface 5b, and a side surface 5c. The third principal surface 5a and the fourth principal surface 5b are opposite to each other. The third principal surface 5a is in contact with the first layer 4. The fourth principal surface 5b is in contact with the third layer 6. The side surface 5c is connected to the third principal surface 5a and the fourth principal surface 5b. The second layer 5 contains Cu as a main component. In this Description, the term “main component” indicates a component with the content of more than 50%. The second layer 5 is preferably made of Cu.

The third layer 6 is made of Ti. The material of the third layer 6 is not limited to the above-mentioned example. In another example, the third layer 6 may be a multilayer body.

The IDT electrode 3 further includes a barrier layer 7. The barrier layer 7 is an outer layer. The barrier layer 7 is disposed on the side surface 5c of the second layer 5. In more detail, the barrier layer 7 covers the side surface 5c. In this preferred embodiment, a thickness of a portion of the barrier layer 7, the portion being disposed on the side surface 5c of the second layer 5, is greater than that of the first layer 4. However, the thickness of the first layer 4 may be greater than that of the above-mentioned portion of the barrier layer 7. Alternatively, the thickness of the first layer 4 may be the same as that of the above-mentioned portion of the barrier layer 7. As illustrated in FIG. 2, a boundary A between the side surface 5c of the second layer 5 and the barrier layer 7 is positioned on the second principal surface 4b of the first layer 4. In more detail, the boundary A is positioned on an inner side than an end of the second principal surface 4b.

In this preferred embodiment, the barrier layer 7 is made of an oxide of Mn. However, the barrier layer 7 simply needs to be made of a metal oxide. The barrier layer 7 is preferably made of an oxide of one type of metal selected from the group consisting of Mn, Al, Mg, and Sn.

A protective film 8 is disposed on the piezoelectric substrate 2 and covers the IDT electrode 3. The protective film 8 is made of silicon oxide. In more detail, the protective film 8 is made of SiO₂. However, the material of the protective film 8 is not limited to the above-mentioned example and may be made of, for example, silicon oxynitride.

Some of the unique features of this preferred embodiment are that the boundary A between the side surface 5c of the second layer 5 and the barrier layer 7 is positioned on the second principal surface 4b of the first layer 4 and the barrier layer 7 does not reach the piezoelectric substrate 2. With such an arrangement, Cu of the IDT electrode 3 can be more reliably reduced or prevented from diffusing into the piezoelectric substrate 2. In addition, the above-mentioned Cu can be effectively reduced or prevented from diffusing into the protective film 8. Advantageous effects of preferred embodiments of the present invention will be described in more detail below.

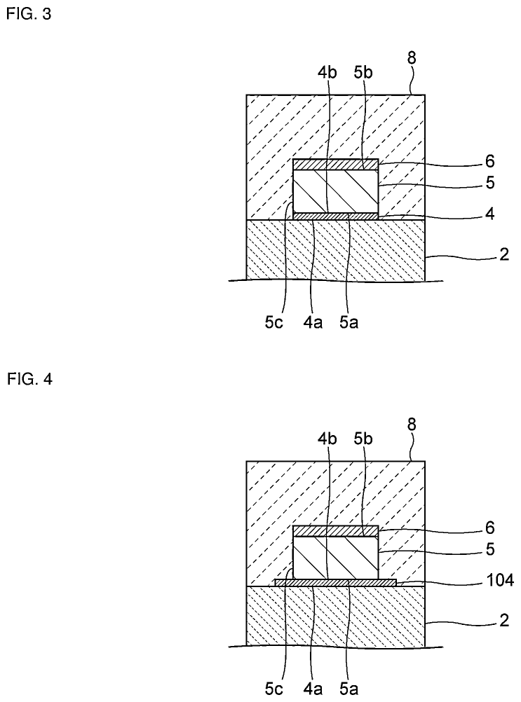

A sample of an acoustic wave filter device according to the first preferred embodiment was prepared. Furthermore, a sample of an acoustic wave filter device according to a first comparative example and a sample of an acoustic wave filter device according to a second comparative example were prepared. A plurality of acoustic wave filter devices was prepared for each type of the above-mentioned acoustic wave filter devices. As illustrated in FIG. 3, the acoustic wave device according to the first comparative example is different from the acoustic wave device according to the first preferred embodiment in that the IDT electrode does not include the barrier layer. As illustrated in FIG. 4, the second comparative example is also different from the first preferred embodiment in that the IDT electrode does not include the barrier layer. Moreover, in the second comparative example, a first layer 104 has a greater width than the second layer 5. This configuration is similar to that disclosed in Japanese Unexamined Patent Application Publication No. 2017-157944. Here, a width of the electrode finger indicates a size of the electrode finger along the propagation direction of the acoustic wave.

Design parameters of the acoustic wave device according to the first preferred embodiment are as follows.

Material of the piezoelectric substrate 2: 128° rotated Y cut X SAW propagation LiNbO₃

First layer 4: material . . . NiCr, thickness . . . 6 nm

Second layer 5: material . . . Cu, thickness . . . 300 nm

Third layer 6: material . . . Ti, thickness . . . 8 nm

Barrier layer 7: material . . . oxide of Mn, thickness . . . 15 nm, position . . . formed only on the side surface 5c of the second layer 5.

Protective film 8: material . . . SiO₂, thickness . . . 1110 nm

Wavelength λ in the IDT electrode 3: 4 μm

Design parameters of the acoustic wave devices according to the first comparative example and the second comparative example are as follows.

Material of the piezoelectric substrate: 128° rotated Y cut X SAW propagation LiNbO₃

First layer: material . . . NiCr, thickness . . . 6 nm

Second layer: material . . . Cu, thickness . . . 300 nm

Third layer: material . . . Ti, thickness . . . 8 nm

Wavelength λ in the IDT electrode: 4 μm

A high temperature loading test was carried out on the sample of the acoustic wave device 1 according to the first preferred embodiment, the sample of the acoustic wave filter device according to the first comparative example, and the sample of the acoustic wave filter device according to the second comparative example. In the test, the temperature was set to 125° C., and a DC voltage of 3 V was applied between the first busbar and the second busbar of the IDT electrode. Filter electrical characteristics were measured at intervals of a predetermined time in the above-mentioned state.

As a result of carrying out the high temperature loading test, with respect to the first comparative example, deterioration of insertion loss was found in all samples in the measurement after a test time of 200 hours. With respect to the second comparative example, deterioration of the insertion loss was found in some of samples in the measurement after a test time of 500 hours. In the other samples of the second comparative example, deterioration of an insulation resistance value was confirmed. As a result of observing the electrode fingers of the samples for which the deterioration of the insulation resistance value was confirmed, diffusion of Cu in the second layer 5 into LiNbO₃ in the piezoelectric substrate 2 was confirmed. In other words, the structure disclosed in Japanese Unexamined Patent Application Publication No. 2017-157944 can reduced or prevent the diffusion of Cu in the second layer 5 into LiNbO₃ to some extent, but it cannot provide a sufficient effect meeting the market demand.

By contrast, in the sample of the acoustic wave device 1 according to the first preferred embodiment, no deterioration was found in both the insertion loss and the insulation resistance value even after a test time of 1000 hours.

From the above-described results, it was discovered and confirmed that reliability can be increased by forming the barrier layer 7 on the side surface 5c of the second layer 5 and by arranging the boundary A between the second layer 5 and the barrier layer 7 to be positioned on the second principal surface 4b of the first layer 4. This represents an effect due to the feature that a distance between the second layer 5 and the piezoelectric substrate 2 is increased and a diffusion path of Cu is cut off by the barrier layer 7.

In the acoustic wave device 1, the first layer 4 defines and functions as a close contact layer. Here, the thickness of the first layer 4 is as thin as about 6 nm, for example. This ensures a low insertion loss of the acoustic wave filter device. In addition, the barrier layer 7 formed on the side surface 5c of the second layer 5 reduces or prevents electrochemical migration of Cu in the second layer 5. Accordingly, an electric power handling capacity can be increased.

The thickness of the first layer 4 is desirably within a range of about 2 nm or more and about 10 nm or less, for example. If the thickness of the first layer 4 is less than about 2 nm, there is a possibility that the diffusion of Cu in the second layer 5 into the piezoelectric substrate 2 is hard to reduce or prevent, or that the electric power handling capacity deteriorates. On the other hand, if the thickness of the first layer 4 is more than about 10 nm, there is a possibility that the insertion loss of the device increases.

The first layer 4 is made of NiCr in this preferred embodiment. In another example, Ti, Ni, Cr, or the like may be used as the material of the first layer 4. The first layer 4 is desirably formed of a metal-containing conductor. Using such a conductor makes an electromechanical coupling coefficient harder to reduce and characteristics of the device harder to deteriorate.

The thickness of the barrier layer 7 is desirably within a range of about 10 nm or more and about 20 nm or less, for example. If the thickness of the barrier layer 7 is less than about 10 nm, there is a possibility that barrier performance becomes insufficient, and that the diffusion of Cu is hard to reduce or prevent. On the other hand, if the thickness of the barrier layer 7 is more than about 20 nm, a ratio of the barrier layer 7 to a cross-sectional area of the electrode finger increases, and a percentage of the second layer 5 reduces. Accordingly, electrical resistance of the electrode finger increases.

By setting the thickness of the barrier layer 7 to be greater than that of the first layer 4 as described above, it is possible to realize the device which has good reliability due to prevention of the diffusion, which has a high electric power handling capacity, and in which the insertion loss is small.

As in this preferred embodiment, the third layer 6 is preferably disposed on the second layer 5. With the presence of the third layer 6, Cu in the second layer 5 can be effectively prevented from diffusing into the protective film 8. In addition, oxidation of Cu in the second layer 5 can be reduced or prevented.

A non-limiting example of a method of manufacturing the acoustic wave device 1 according to the first preferred embodiment will be described below. At the outset, the first layer 4, an electrode pattern for the second layer 5, and the third layer 6 are formed on the piezoelectric substrate 2 by the liftoff process, for example. The electrode pattern for the second layer 5 is formed of a metal that is obtained by adding 0.1 atom % to 20 atom % of Mn to Cu. Alternatively, the first layer 4, the electrode pattern for the second layer 5, and the third layer 6 may be formed by patterning with etching of each of those metal layers.

Then, heat treatment is performed for about 1 hour at 200° C. to 400° C. During the heat treatment, Mn in the electrode pattern binds to oxygen in an atmosphere at a side surface of the electrode pattern, thus forming an oxide film. Other surfaces of the electrode pattern except for the side surface are covered by the first layer 4 and the third layer 6. Accordingly, oxidation of Mn does not progress at those other surfaces of the electrode pattern. With the oxidation of Mn, Mn in the electrode pattern additionally migrates to the side surface of the electrode pattern. Then, the oxidation of Mn further progresses. As a result, the second layer 5, defined by a Cu layer, is formed from the electrode pattern made of a mixture of Cu and Mn. In addition, the barrier layer 7 made of an oxide of Mn is formed on the side surface 5c of the second layer 5. The barrier layer 7 is not formed directly in an electrode-finger not-formed region, such as a zone between the electrode fingers on the piezoelectric substrate 2. At the same time as forming the IDT electrode 3, the reflector 9A and the reflector 9B are also formed. Thereafter, the protective film 8 is formed on the piezoelectric substrate 2 to cover the IDT electrode 3 by the sputtering process, for example.

Prior to performing the above-described heat treatment, namely in a state in which a small amount of Mn is mixed in the Cu layer forming the electrode pattern, resistivity of the Cu layer is high, and barrier performance for the diffusion of Cu is not yet developed. The barrier performance is developed with Mn migrating outward due to the heat treatment and forming the oxide film. Thus, a Mn concentration in a central Cu portion reduces, and the central Cu portion becomes nearly pure Cu. As a result, the resistivity of the Cu layer reduces, and the advantageous effects of this application are obtained.

The second layer 5 simply needs to contain Cu as a main component, and Mn may remain in the second layer 5. The concentration of Mn in the second layer 5 is preferably about 0.02 atm % or less, for example. In this case, an increase in resistivity of the second layer 5 in comparison with that of pure Cu can be held relatively small. However, as described above, the second layer 5 is preferably made of Cu containing no impurities. In such a case, the resistivity of the second layer 5 can be further reduced.

As metal elements migrating like Mn and forming stable oxide films, there are, for example, Al, Mg, and Sn. Among those examples, the metal element capable of minimizing the electrical resistance of the electrode finger when added to Cu to form the barrier layer 7 is Mn. In the case of adding Ag as the metal element other than the above-described examples, the electric power handling capacity of the IDT electrode 3 can be increased.

When the protective film 8 is made of an oxide such as SiO₂, the above-described heat treatment may be performed after forming the protective film 8 instead of after forming the electrode pattern. In that case, Mn forms the oxide film by binding to oxygen in the protective film 8 instead of an atmosphere.

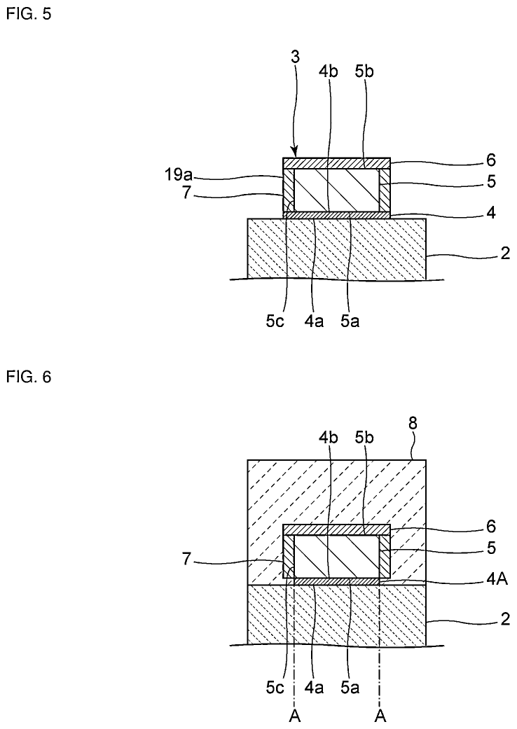

The protective film 8 is not always needed to be formed. In a first modification of the first preferred embodiment illustrated in FIG. 5, the protective film 8 is not formed on the piezoelectric substrate 2. In this case, the diffusion of Cu in the second layer 5 into the piezoelectric substrate 2 can also be more reliably reduced or prevented as in the first preferred embodiment.

In the first preferred embodiment, the boundary A between the second layer 5 and the barrier layer 7 is positioned on the inner side than the end of the second principal surface 4b of the first layer 4. However, the boundary A simply needs to be positioned on the second principal surface 4b. In a second modification of the first preferred embodiment illustrated in FIG. 6, the boundary A is positioned at an end of a second principal surface 4b of a first layer 4A. In this case as well, the distance between the second layer 5 and the piezoelectric substrate 2 is increased and the diffusion path of Cu is cut off by the barrier layer 7. Because the barrier layer 7 does not reach the piezoelectric substrate 2, a path along which Cu in the second layer 5 reaches the piezoelectric substrate 2 while migrating through the barrier layer 7 is also not generated. Accordingly, the diffusion of Cu in the second layer 5 into the piezoelectric substrate 2 can be more reliably reduced or prevented as in the first preferred embodiment.

However, like the first preferred embodiment, the boundary A between the second layer 5 and the barrier layer 7 is preferably positioned on the inner side than the end of the second principal surface 4b of the first layer 4. With that arrangement, the diffusion path of Cu between the second layer 5 and the piezoelectric substrate 2 can be more reliably cut off.

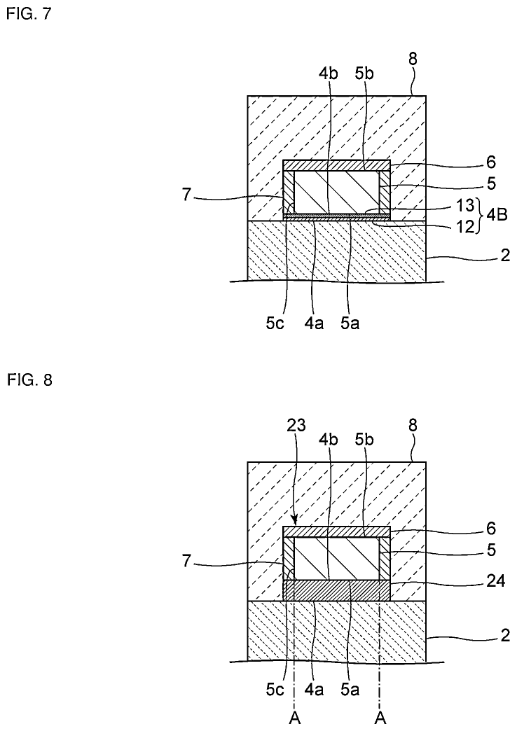

As described above, the first layer 4 may be a multilayer body. In a third modification of the first preferred embodiment illustrated in FIG. 7, a first layer 4B includes a first metal layer 12 and a second metal layer 13. The first metal layer 12 is a close contact layer made of NiCr. The second metal layer 13 is made of Ag. However, the number of laminated layers in the first layer 4B and materials of the individual layers are not limited to the above-mentioned examples.

FIG. 8 is a transverse sectional view of an electrode finger in a second preferred embodiment. In this Description, the wording “transverse cross-section of the electrode finger” indicates a cross-section along a direction orthogonal to an extension direction of the electrode finger.

This preferred embodiment is different from the first preferred embodiment in that a first layer 24 has a greater thickness than a portion of the barrier layer 7, the portion being disposed on the side surface 5c of the second layer 5. Except for the above-mentioned point, an acoustic wave device according to this preferred embodiment has a similar configuration to that of the acoustic wave device 1 according to the first preferred embodiment.

As in the first preferred embodiment, this preferred embodiment can also more reliably reduce or prevent the diffusion of Cu in the second layer 5 into the piezoelectric substrate 2. The advantageous effects of this preferred embodiment will be described in more detail below.

A sample of an acoustic wave filter device according to the second preferred embodiment was prepared. Furthermore, a sample of an acoustic wave filter device according to a third comparative example and a sample of an acoustic wave filter device according to a fourth comparative example were prepared. A plurality of acoustic wave filter devices was prepared for each type of the above-mentioned acoustic wave filter devices. The acoustic wave device according to the third comparative example is different from the acoustic wave device according to the second preferred embodiment in that the IDT electrode does not include the barrier layer. The fourth comparative example is also different from the second preferred embodiment in that the IDT electrode does not include the barrier layer. In addition, in the fourth comparative example, the first layer has a greater width than the second layer as in the second comparative example illustrated in FIG. 4.

Design parameters of the acoustic wave device according to the second preferred embodiment are as follows.

Material of the piezoelectric substrate 2: 128° rotated Y cut X SAW propagation LiNbO₃

First layer 24: material . . . NiCr, thickness . . . 60 nm

Second layer 5: material . . . Cu, thickness . . . 300 nm

Third layer 6: material . . . Ti, thickness . . . 8 nm

Barrier layer 7: material . . . oxide of Mn, thickness . . . 5 nm, position . . . formed only on the side surface 5c of the second layer 5.

Protective film 8: material . . . SiO₂, thickness . . . 1110 nm

Wavelength λ in an IDT electrode 23: 4 μm

Design parameters of the acoustic wave devices according to the third comparative example and the fourth comparative example are as follows.

Material of the piezoelectric substrate: 128° rotated Y cut X SAW propagation LiNbO₃

First layer: material . . . NiCr, thickness . . . 60 nm

Second layer: material . . . Cu, thickness . . . 300 nm

Third layer: material . . . Ti, thickness . . . 8 nm

Wavelength λ in the IDT electrode: 4 μm

A similar high temperature loading test to that described above was carried out on the sample of the acoustic wave filter device according to the second preferred embodiment, the sample of the acoustic wave filter device according to the third comparative example, and the sample of the acoustic wave filter device according to the fourth comparative example. As a result of carrying out the high temperature loading test, with respect to each of the third comparative example and the fourth comparative example, deterioration of the insertion loss was found in some of samples in the measurement after a test time of 500 hours. In the other samples of each of the third comparative example and the fourth comparative example except for the samples in which the deterioration of the insertion loss was found, deterioration of an insulation resistance value was confirmed. As a result of observing the electrode fingers of the samples for which the deterioration of the insulation resistance value was confirmed, the diffusion of Cu in the second layer into LiNbO₃ in the piezoelectric substrate was confirmed. As is apparent from the result of the test on the fourth comparative example, by using the structure disclosed in Japanese Unexamined Patent Application Publication No. 2017-157944 and thickening the first layer, the diffusion of Cu into LiNbO₃ can be suppressed to some extent, but a sufficient effect meeting the market demand cannot be obtained.

By contrast, in the sample of the acoustic wave filter device according to the second preferred embodiment, no deterioration was found in both the insertion loss and the insulation resistance value even after a test time of 1000 hours.

From the above-described results, it was confirmed that a certain level of effect in improving the reliability by thickening the first layer and increasing the distance between the second layer and the piezoelectric substrate was obtained, but the effect was not yet sufficient. Moreover, it was discovered that the reliability can be increased by, as in the second preferred embodiment illustrated in FIG. 8, forming the barrier layer 7 on the side surface 5c of the second layer 5 and arranging the boundary A between the second layer 5 and the barrier layer 7 to be positioned on a second principal surface 4b of the first layer 24. This represents an effect due to the feature that the distance between the second layer 5 and the piezoelectric substrate 2 is further increased and the diffusion path is cut off by the barrier layer 7.

The thickness of the first layer 24 is desirably about 20 nm or more, for example. Under this condition, the diffusion of Cu in the second layer 5 can be effectively reduced or prevented. On the other hand, there is not a specific upper limit in the thickness of the first layer 24. However, the thickness of the first layer 24 is preferably about 30% or less of the wavelength λ. If the thickness of the IDT electrode 23 is too thick, there is a possibility that the electrode pattern becomes hard to form.

By setting the thickness of the first layer 24 to be greater than that of the barrier layer 7 as described above, the diffusion between the second layer 5 and the piezoelectric substrate 2 can be effectively reduced or prevented. It is, therefore, possible to realize the acoustic wave device which has good reliability, of which electrode finger has a low electrical resistance, and in which the loss is small.

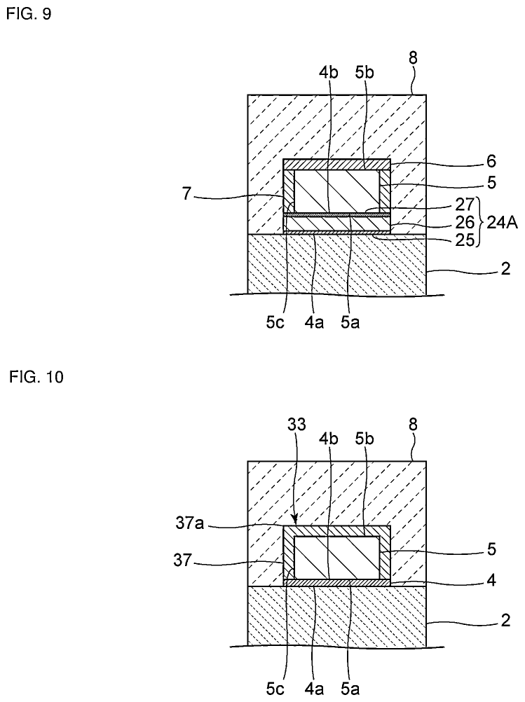

As in the modification illustrated in FIG. 7, the first layer 24 may be a multilayer body. In a modification of the second preferred embodiment illustrated in FIG. 9, a first layer 24A includes a first metal layer 25, a second metal layer 26, and a third metal layer 27. The first metal layer 25 is a close contact layer made of NiCr. The second metal layer 26 is made of Pt. The third metal layer 27 is made of Ti. However, the number of laminated layers in the first layer 24A and materials of the individual layers are not limited to the above-mentioned examples.

In third and subsequent preferred embodiments described below, the thickness of the first layer 4 may also be greater than that of a portion of a barrier layer 37, the portion being disposed on the side surface 5c of the second layer 5.

FIG. 10 is a transverse sectional view of an electrode finger in a third preferred embodiment.

This preferred embodiment is different from the first preferred embodiment in that an IDT electrode 33 includes the barrier layer 37 on both the side surface 5c and the fourth principal surface 5b of the second layer 5, and that the third layer 6 is not disposed. Except for the above-mentioned point, an acoustic wave device according to this preferred embodiment has a similar configuration to that of the acoustic wave device 1 according to the first preferred embodiment.

Since the barrier layer 37 covers the side surface 5c and the fourth principal surface 5b of the second layer 5, Cu in the second layer 5 can be reduced or prevented from diffusing into the protective film 8. Furthermore, as in the first preferred embodiment, the diffusion of Cu in the second layer 5 into the piezoelectric substrate 2 can be more reliably reduced or prevented.

In forming the IDT electrode 33 in this preferred embodiment, the heat treatment is performed, for example, in a similar manner to that in forming the IDT electrode 3 in the first preferred embodiment except that the third layer 6 is not disposed. During the heat treatment, Mn in the electrode pattern for the second layer 5 binds to oxygen in an atmosphere at the side surface and the upper surface of the electrode pattern, thus forming an oxide film. Here, the wording “upper surface” indicates an upper surface as viewed in FIG. 10. With oxidation of Mn, Mn in the electrode pattern additionally migrates to the side surface and the upper surface of the electrode pattern. Then, the oxidation of Mn further progresses. As a result, the second layer 5 defined by a Cu layer is formed from the electrode pattern made of a mixture of Cu and Mn. In addition, the barrier layer 37 made of an oxide of Mn is formed on the side surface 5c and the fourth principal surface 5b of the second layer 5.

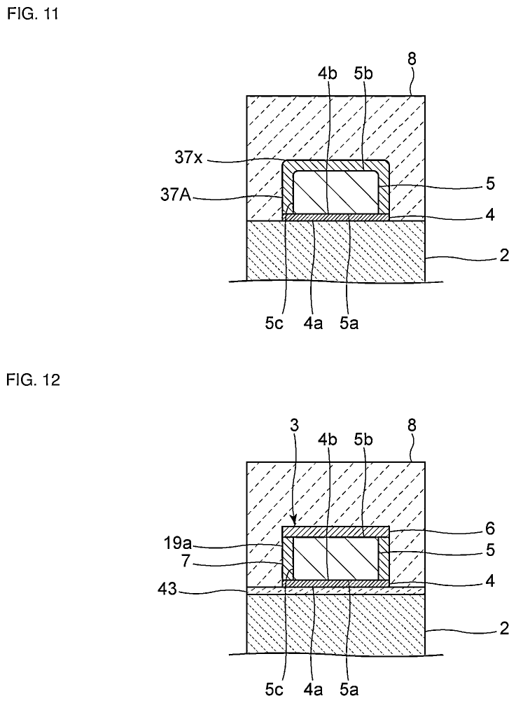

As illustrated in FIG. 10, the barrier layer 37 includes a connection portion 37a. In more detail, the connection portion 37a is a portion where a portion of the barrier layer 37 disposed on the side surface 5c of the second layer 5 and a portion of the barrier layer 37 disposed on the fourth principal surface 5b are connected to each other. In this preferred embodiment, the connection portion 37a has a shape defined by two linear lines joining with each other when viewed in a transverse cross-section of the IDT electrode 33. Thus, the connection portion 37a is formed as an angled corner portion. More specifically, the connection portion 37a is formed as the angled corner portion at each of a boundary between the barrier layer 37 and the protective film 8 and a boundary between the barrier layer 37 and the second layer 5. However, the shape of the connection portion 37a is not limited to the above-mentioned example. In a modification of the third preferred embodiment illustrated in FIG. 11, a connection portion 37x of a barrier layer 37A has a curved shape. In more detail, the connection portion 37x has a curved shape at each of a boundary between the barrier layer 37A and the protective film 8 and a boundary between the barrier layer 37A and the second layer 5.

FIG. 12 is a transverse sectional view of an electrode finger in a fourth preferred embodiment.

This preferred embodiment is different from the first preferred embodiment in that a dielectric film 43 is disposed between the piezoelectric substrate 2 and the IDT electrode 3. Except for the above-mentioned point, an acoustic wave device according to this preferred embodiment has a similar configuration to that of the acoustic wave device 1 according to the first preferred embodiment.

With the presence of the dielectric film 43, the electromechanical coupling coefficient can be adjusted to a proper value, and the diffusion of Cu in the second layer 5 into the piezoelectric substrate 2 can be effectively reduced or prevented. A thickness of the dielectric film 43 is preferably about 1% or less of the wavelength λ, for example. Under this condition, the electromechanical coupling coefficient can be prevented from becoming too small. Accordingly, the insertion loss is hard to increase.

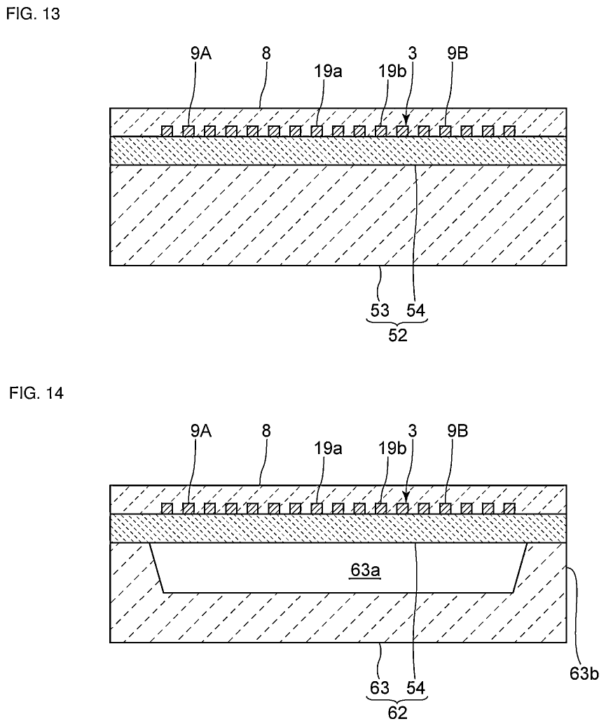

FIG. 13 is a front sectional view of an acoustic wave device according to a fifth preferred embodiment.

This preferred embodiment is different from the first preferred embodiment in that a piezoelectric substrate 52 is a multilayer substrate including a support substrate 53 and a piezoelectric layer 54. The piezoelectric layer 54 is disposed on the support substrate 53. The IDT electrode 3 is disposed on the piezoelectric layer 54. Except for the above-mentioned point, the acoustic wave device according to this preferred embodiment has a similar configuration to that of the acoustic wave device 1 according to the first preferred embodiment.

The piezoelectric layer 54 is made of lithium niobate. However, the material of the piezoelectric layer 54 is not limited to the above-mentioned example and can also be selected from among, for example, lithium tantalate, zinc oxide, aluminum nitride, quartz, and PZT.

The support substrate 53 is made of silicon. However, the material of the support substrate 53 is not limited to the above-mentioned example and can also be selected from among, for example, piezoelectric bodies such as aluminum oxide, lithium tantalate, lithium niobate, and quartz, a variety of ceramics such as alumina, sapphire, magnesia, silicon nitride, aluminum nitride, silicon carbide, zirconia, cordierite, mullite, steatite, and forsterite, dielectrics such as diamond and glass, semiconductors such as gallium nitride, and resins.

In this preferred embodiment as well, the IDT electrode 3 has a similar configuration to that in the first preferred embodiment. Accordingly, the diffusion of Cu of the IDT electrode 3 into the piezoelectric substrate 52 and the protective film 8 can be more reliably reduced or prevented.

A thickness of the piezoelectric layer 54 is preferably about a or less, for example. In this case, excitation efficiency of the acoustic wave can be increased.

FIG. 14 is a front sectional view of an acoustic wave device according to a sixth preferred embodiment.

This preferred embodiment is different from the fifth preferred embodiment in that a support substrate 63 includes a cavity 63a and a support portion 63b. Except for the above-mentioned point, the acoustic wave device according to the sixth preferred embodiment has a similar configuration to that of the acoustic wave device according to the fifth preferred embodiment.

The cavity 63a in the support substrate 63 is surrounded by the support portion 63b and is opened toward the piezoelectric layer 54. The support substrate 63 supports the piezoelectric layer 54 at the support portion 63b. In this case, the excitation efficiency of the acoustic wave can be effectively increased.

In this preferred embodiment, the IDT electrode 3 has a similar configuration to that in the fifth preferred embodiment. Accordingly, the diffusion of Cu of the IDT electrode 3 into a piezoelectric substrate 62 and the protective film 8 can be more reliably reduced or prevented.

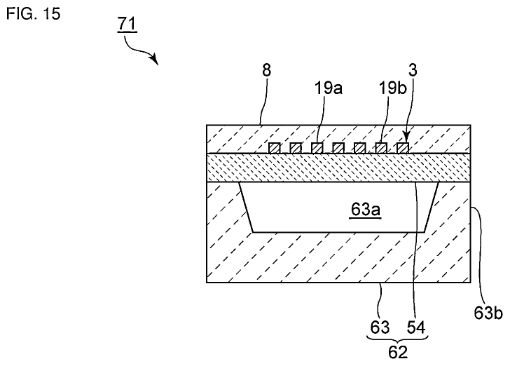

FIG. 15 is a front sectional view of an acoustic wave device according to a seventh preferred embodiment.

This preferred embodiment is different from the first preferred embodiment in that the acoustic wave device 71 utilizes a bulk wave in a thickness-shear primary mode. In more detail, when a thickness of the piezoelectric layer 54 is denoted by d and an electrode finger pitch of the IDT electrode 3 is denoted by p, d/p is about 0.5 or less in this preferred embodiment, for example. With such a configuration, the bulk wave in the thickness-shear primary mode can be utilized as a main mode. The acoustic wave device 71 includes no reflectors. Except for the above-mentioned point, the acoustic wave device 71 according to this preferred embodiment has a similar configuration to that of the acoustic wave device according to the sixth preferred embodiment.

In the case of utilizing the bulk wave in the thickness-shear primary mode, propagation loss is small even when the number of electrode fingers in a reflector is reduced. Therefore, the size of the acoustic wave device 71 can be effectively reduced. In addition, since the IDT electrode 3 has a similar configuration to that in the sixth preferred embodiment, the diffusion of Cu of the IDT electrode 3 into the piezoelectric substrate 62 and the protective film 8 can be more reliably reduced or prevented.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate; and
an IDT electrode including a plurality of electrode fingers, a first layer on the piezoelectric substrate, and a second layer on the first layer and including Cu as a main component; wherein
the first layer includes a first principal surface on a side closest to the piezoelectric substrate and a second principal surface in contact with the second layer;
the second layer includes a third principal surface in contact with the first layer, a fourth principal surface opposite to the third principal surface, and a side surface connected to the third principal surface and the fourth principal surface;
the IDT electrode further includes an outer layer on the side surface of the second layer; and
a boundary between the side surface of the second layer and the outer layer is on the second principal surface of the first layer, and the outer layer does not reach the piezoelectric substrate.

2. The acoustic wave device according to claim 1, wherein the boundary between the side surface of the second layer and the outer layer is on an inner side spaced from an end of the second principal surface of the first layer.

3. The acoustic wave device according to claim 1, further comprising a protective film on the piezoelectric substrate and covering the IDT electrode.

4. The acoustic wave device according to claim 2, further comprising a protective film on the piezoelectric substrate and covering the IDT electrode.

5. The acoustic wave device according to claim 1, wherein the IDT electrode further includes a third layer on the fourth principal surface of the second layer.

6. The acoustic wave device according to claim 2, wherein the IDT electrode further includes a third layer on the fourth principal surface of the second layer.

7. The acoustic wave device according to claim 3, wherein the IDT electrode further includes a third layer on the fourth principal surface of the second layer.

8. The acoustic wave device according to claim 4, wherein the IDT electrode further includes a third layer on the fourth principal surface of the second layer.

9. The acoustic wave device according to claim 1, wherein the outer layer is on the side surface and the fourth principal surface of the second layer.

10. The acoustic wave device according to claim 2, wherein the outer layer is on the side surface and the fourth principal surface of the second layer.

11. The acoustic wave device according to claim 3, wherein the outer layer is on the side surface and the fourth principal surface of the second layer.

12. The acoustic wave device according to claim 4, wherein the outer layer is on the side surface and the fourth principal surface of the second layer

13. The acoustic wave device according to claim 1, wherein a thickness of a portion of the outer layer on the side surface of the second layer, is greater than a thickness of the first layer.

14. The acoustic wave device according to claim 2, wherein a thickness of a portion of the outer layer on the side surface of the second layer, is greater than a thickness of the first layer.

15. The acoustic wave device according to claim 1, wherein a thickness of the first layer is greater than a thickness of a portion of the outer layer on the side surface of the second layer.

16. The acoustic wave device according to claim 1, wherein the outer layer is made of a metal oxide.

17. The acoustic wave device according to claim 16, wherein the outer layer is made of an oxide of one metal selected from the group consisting of Mn, Al, Mg, and Sn.

18. The acoustic wave device according to claim 17, wherein the outer layer is made of the oxide of Mn.

19. The acoustic wave device according to claim 1, wherein the piezoelectric substrate includes a support substrate and a piezoelectric layer on the support substrate.

20. The acoustic wave device according to claim 1, further comprising a dielectric film between the piezoelectric substrate and the IDT electrode; wherein
when a wavelength specified by an electrode finger pitch of the IDT electrode is denoted by λ, a thickness of the dielectric film is about 1% or less of the wavelength λ.
